(19) United States
(12) Patent Application Publication
(10) Pub. No.: US 2003/0209760 A1
(43) Pub. Date: Nov. 13, 2003

(54) Semiconductor integrated circuit and method of fabricating the same

(75) Inventor: Shinya Maruyama, Kanagawa (JP)

Correspondence Address: YOUNG & THOMPSON, 745 SOUTH 23RD STREET 2ND FLOOR, ARLINGTON, VA, 22202

(73) Assignee: NEC ELECTRONICS CORPORATION, Kanagawa (JP)

(21) Appl. No.: 10/424,938

(22) Filed: Apr. 29, 2003

(30) Foreign Application Priority Data
May 10, 2002 (JP) 2002-135186

(51) Int. Cl. H01L 27/01

(52) U.S. Cl. 257/347

(57) ABSTRACT

An SOI (Silicon On Insulator) wafer which has a BOX (Buried Oxide) layer and an SOI layer formed on a silicon substrate is prepared. A silicon oxide film and a silicon nitride film are deposited and patterned on the surface of the SOI layer. Then, with the silicon oxide film and silicon nitride film used as masks, dry etching is performed to form trenches, which do not reach the BOX layer, in the SOI layer. Next, round oxidation is executed by performing thermal oxidation on the SOI wafer, thereby forming a silicon oxide film in that region of the SOI layer which corresponds to the bottom and sides of each trench. Then, with a photoresist as a mask, the SOI layer which is located at the bottoms of the trenches is selectively etched out to form trenches which reach the BOX layer. Then, an STI (Shallow Trench Isolation) region is formed in those trenches.

### BACKGROUND OF THE INVENTION

1. Field of the Invention

The present invention relates to a semiconductor integrated circuit which is formed in an SOI (Silicon On Insulator) layer and a method of fabricating the same, and, more particularly, to a method of forming a device isolation region without degrading the performance of a transistor.

2. Description of the Related Art

There have been developed techniques of forming a semiconductor integrated circuit including devices, such as MOSFETs (Metal Oxide Semiconductor Field Effect Transistors) in an SOI layer by forming a BOX (Buried Oxide) layer on a silicon substrate and forming the SOI layer on the BOX layer.

In such a semiconductor integrated circuit, the SOI layer is insulated from the silicon substrate by the BOX layer. This can reduce the source-drain capacitance of transistors formed in the SOI layer, thereby improving the speed of the transistors. The threshold voltage of the transistors can be decreased by increasing the voltage of a body which is formed directly under the gate electrode of each transistor. It is also possible to prevent the transistors from being influenced by a variation in the voltage of the substrate.

In such a semiconductor integrated circuit, an STI (Shallow Trench Isolation) region is formed in the SOI layer in order to electrically isolate the individual devices from one another. In case where one wants to completely isolate the individual devices from one another, the STI region is formed deep so as to reach the BOX layer.

FIGS. 1A through 1C and FIGS. 2A through 2C are cross-sectional views illustrating a conventional method of forming a semiconductor integrated circuit step by step.

First, as shown in FIG. 1A, an SOI wafer 101 is prepared. In the SOI wafer 101, a silicon substrate 102 is provided, a BOX layer 103 is formed on the silicon substrate 102 and an SOI layer 104 is formed on the BOX layer 103. The SOI layer 104 has a thickness of, for example, 150 nm.

Next, a silicon oxide film (SiO₂ film) 105 is formed on the surface of the SOI layer 104 by thermal oxidizing the SOI wafer 101, as shown in FIG. 1B. Then, a silicon nitride film (Si₃N₄ film) 106 is deposited on the silicon oxide film 105, as shown in FIG. 1C.

Next, as shown in FIG. 2A, a photoresist (not shown) is formed on the silicon nitride film 106 by photolithography. An opening is formed in that region of this photoresist which is reserved for the formation of an STI region in a later process. With the photoresist as a mask, the silicon nitride film 106, the silicon oxide film 105 and the SOI layer 104 are selectively etched out by dry etching, thereby forming trenches 107. At this time, the trenches 107 are formed in such a way as to reach the BOX layer.

Next, as shown in FIG. 2B, the SOI wafer 101 is subjected to thermal oxidation. As a result, a silicon oxide film 109 is formed in that region of the inner surface of each trench 107 where the SOI layer 104 is exposed. This process is called “round oxidation”. The round oxidation is carried out in order to recover from a damage made on the SOI layer 104 by the aforementioned dry etching and round the shape of the trench 107 so as to prevent the formation of pointed portions which would cause concentration of an electric field in the trenches 107.

Next, as shown in FIG. 2C, a silicon oxide film is deposited on the entire surface of the resultant structure by plasma CVD (Chemical vapor Deposition). Then, that silicon oxide film, which is formed in other regions than the inside of the trenches 107, is removed by CMP (Chemical Mechanical Polishing). Thereby, an STI region 112, which is formed of the silicon oxide film, is formed in the trenches 107. Then, devices, such as MOSFETs, are formed in that region in the SOI layer 104 which is defined by the STI region 112, thereby forming a semiconductor integrated circuit.

The prior art however has the following drawbacks. FIG. 3 is a more-detailed cross-sectional view showing the process in FIG. 2B in the conventional fabrication method. As shown in FIG. 3, an oxide 113 is actually formed between the BOX layer 103 and the SOI layer 104 near the trench 107 by round oxidation. This occurs as oxygen goes around to the interface between the BOX layer 103 and the SOI layer 104 from the bottom of the trench 107. A projection 114 is formed on the center portion of the bottom of the trench 107. This occurs as oxygen penetrates the BOX layer 103 at the bottom of the trench 107 and reaches the silicon substrate 102 to oxide the surface of the silicon substrate 102 at the time round oxidation is carried out. The oxide 113 and the projection 114 are not shown in FIG. 2.

If the oxide 113 and the projection 114 are formed in the semiconductor integrated circuit, the SOI layer 104 is bent. The bending of the SOI layer 104 deforms the shape of the portion underlying the channel region of the transistor formed in the SOI layer 104. This results in lower mobility of carriers, which degrade the characteristics of the transistor.

### SUMMARY OF THE INVENTION

Accordingly, it is an object of the present invention to provide a semiconductor integrated circuit formed in an SOI layer in which a device isolation region can be formed without degrading the performance of a transistor, and a method of fabricating the semiconductor integrated circuit.

A semiconductor integrated circuit according to the invention comprises a semiconductor substrate; an insulation film formed on the semiconductor substrate; and a semiconductor layer formed on the insulation film and having first grooves in which an insulator is buried and on sides of which an oxide film of the semiconductor layer is formed in such a way as not to reach the insulation film, and a second groove in which an insulator is buried, which reaches the insulation film and which is formed in a bottom of at least one of the first grooves.

According to the invention, the first grooves which do not reach the insulation film are formed in the semiconductor layer, the second groove which reaches the insulation film is formed in the bottom of at least one of the first grooves, and an insulator is buried in the first and second grooves. Accordingly, an STI region which reaches the insulation film can be formed. As the oxide film of the semiconductor layer is formed on the sides of the first grooves, a damage made on the semiconductor layer can be recovered and the formation of pointed portions can be prevented. Further, as the first grooves do not reach the insulation film, it is possible to prevent oxygen from going around and entering between the insulation film and the semiconductor layer at the time of forming the oxide film of the semiconductor layer on the sides of the first grooves. This can prevent an oxide from being formed between the insulation film and the semiconductor layer. It is also possible to restrain oxygen from penetrating the insulation film and reaching the semiconductor substrate. This can suppress oxidation of the surface of the semiconductor substrate, thereby suppressing expansion of the semiconductor substrate. This makes it possible to prevent the mobility of carriers in the semiconductor layer from dropping, so that transistors with excellent characteristics can be formed in the semiconductor layer.

A method of fabricating a semiconductor integrated circuit according to the invention comprises the steps of forming an insulation film on a semiconductor substrate; forming a semiconductor layer on the insulation film; forming first grooves, which do not to reach the insulation film, in a surface layer of the semiconductor layer; oxidizing inner surfaces of the first grooves in the semiconductor layer; forming a second groove, which reaches the insulation film, in a bottom of at least one of the first grooves; and forming a device isolation region by burying an insulator in the first and second grooves.

According to the invention, the first grooves are formed in such a way as not to reach the insulation film, after which the inner surfaces of the first grooves are oxidized. Thereafter, the second groove which reaches the insulation film is formed in the bottom of at least one of the first grooves. The structure makes it possible to prevent oxygen from going around and entering between the insulation film and the semiconductor layer at the time of oxidizing the inner surfaces of the first grooves. This can prevent an oxide from being formed between the insulation film and the semiconductor layer. It is also possible to restrain oxygen from penetrating the insulation film and reaching the semiconductor substrate. This can suppress oxidation of the surface of the semiconductor substrate, thereby suppressing expansion of the semiconductor substrate, so that the formation of projections on the bottoms of the first grooves can be repressed. Accordingly, it is possible to prevent the semiconductor layer from being bent by the formation of the oxide film. This makes it possible to prevent the mobility of carriers in the semiconductor layer from dropping, thereby prohibiting the characteristics of transistors to be formed in the semiconductor layer from being degraded.

The second groove may be formed only in bottoms of some of the first grooves and may not be formed in bottoms of the remaining first grooves. This makes it possible to form the device isolation region that reaches the insulation film in said some of the first grooves and form the device isolation region that does not reach the insulation film in the remaining first grooves. That is, the device isolation region that reaches the insulation film and the device isolation region that does not reach the insulation film can be formed separately in the same process.

The step of forming the second groove may include the step of: forming a photoresist, having an opening at a region corresponding to the bottom of the at least one first groove, on the semiconductor layer; and etching the semiconductor layer using the photoresist as a mask to thereby selectively remove the semiconductor layer located at the bottom of the at least one first groove. Accordingly, the second groove can be formed without damaging other portions of the first grooves than the bottoms. At this time, those of the first grooves, in whose bottoms the second groove is to be formed, can be selected by forming an opening only in that area of the photoresist which corresponds to some of the first grooves. Accordingly, the device isolation region that reaches the insulation film and the device isolation region that does not reach the insulation film can be formed separately.

The step of forming the first grooves may include the steps of forming a first photoresist on the semiconductor layer, etching the semiconductor layer using the first photoresist as a mask to thereby selectively remove the semiconductor layer, and removing the first photoresist; and the step of forming the second groove may include the steps of forming a second photoresist patterned in a same pattern as the first photoresist, and etching the semiconductor layer using the second photoresist as a mask to thereby selectively remove the semiconductor layer located at the bottom of the at least one first groove. This can allow the first photoresist and the second photoresist to be formed using the same mask, and can thus contribute to reducing the fabrication cost for a semiconductor integrated circuit.

The step of forming the second groove may include the steps of forming side walls covering sides of the at least one first groove, and etching the semiconductor layer using the side walls as a mask to thereby selectively remove the semiconductor layer located at the bottom of the at least one first groove, and the step of forming the side walls may include the steps of forming a nitride film on an entire surface of the semiconductor layer, and performing etch-back of the nitride film to leave the nitride film formed on the sides of the at least one first groove and remove the nitride film formed on a region excluding the sides of the at least one first groove. This eliminates the need for forming a photoresist at the time of forming the second groove and can allow the second groove to be formed in a self-aligned manner with respect to the first groove. It is therefore possible to form a device isolation region small enough that a photoresist cannot be patterned.

According to the present invention, as elaborated above, the first grooves are formed in such a way as not to reach the insulation film, after which the inner surfaces of the first grooves are oxidized, so that it is possible to prevent oxygen from going around and entering between the insulation film and the semiconductor layer at the time of forming the oxide film, and to restrain oxygen from penetrating the insulation film and reaching the semiconductor substrate. It is therefore possible to prohibit the formation of an oxide between the insulation film and the semiconductor layer and prohibit projections from being formed on the bottoms of the first grooves. This makes it possible to form a device isolation region without degrading the characteristics of transistors formed in the semiconductor layer.

### BRIEF DESCRIPTION OF THE DRAWINGS

FIGS. 1A through 1C are cross-sectional views illustrating the conventional method of forming a semiconductor integrated circuit step by step;

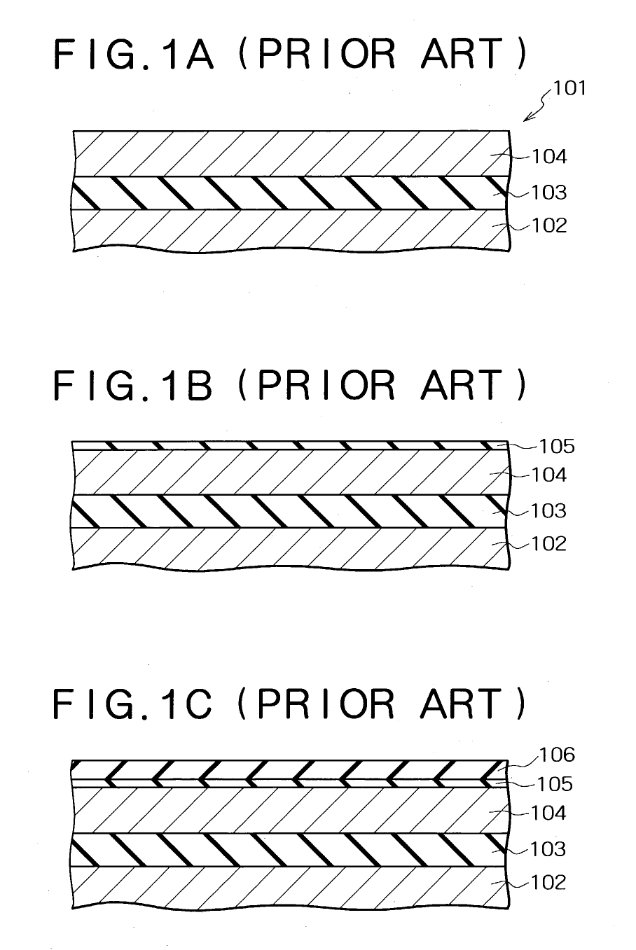

FIGS. 2A through 2C are cross-sectional views illustrating the conventional method of forming the semiconductor integrated circuit step by step and show the next process to the process in FIG. 1C;

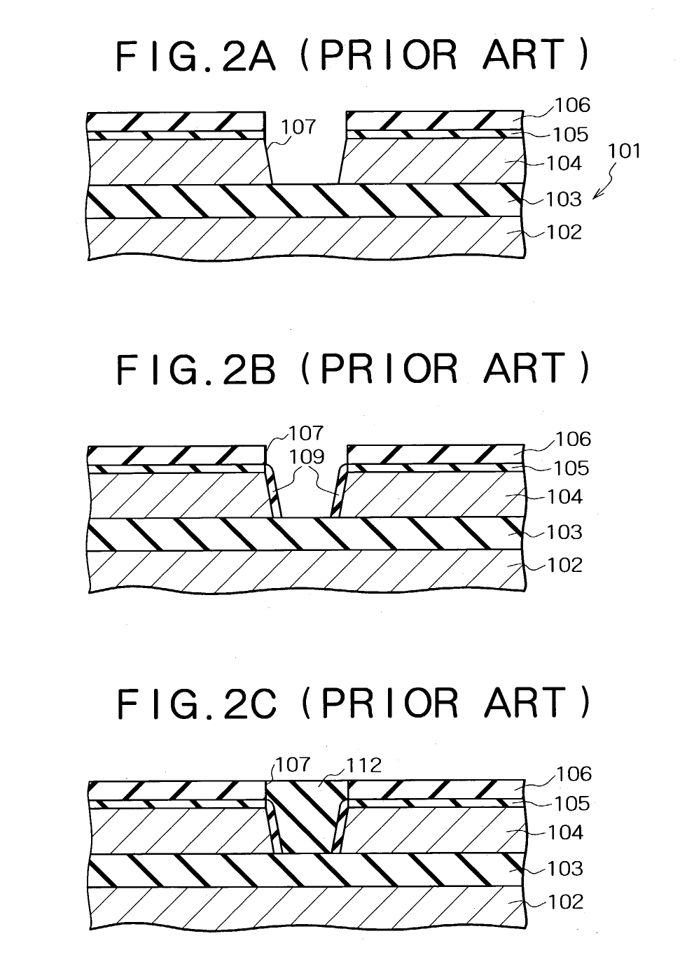

FIG. 3 is a more-detailed cross-sectional view showing the process in FIG. 2B in the conventional fabrication method;

FIGS. 4A through 4C are step-by-step cross-sectional views illustrating a method of forming a semiconductor integrated circuit according to a first embodiment of the invention;

FIGS. 5A through 5C are step-by-step cross-sectional views illustrating the method of forming the semiconductor integrated circuit according to the embodiment and show the next process to the process in FIG. 4C;

FIG. 6 is a cross-sectional view illustrating a method of forming a semiconductor integrated circuit according to a second embodiment of the invention; and

FIGS. 7A through 7C are step-by-step cross-sectional views illustrating a method of forming a semiconductor integrated circuit according to a third embodiment of the invention.

### DETAILED DESCRIPTION OF THE PREFERRED EMBODIMENTS

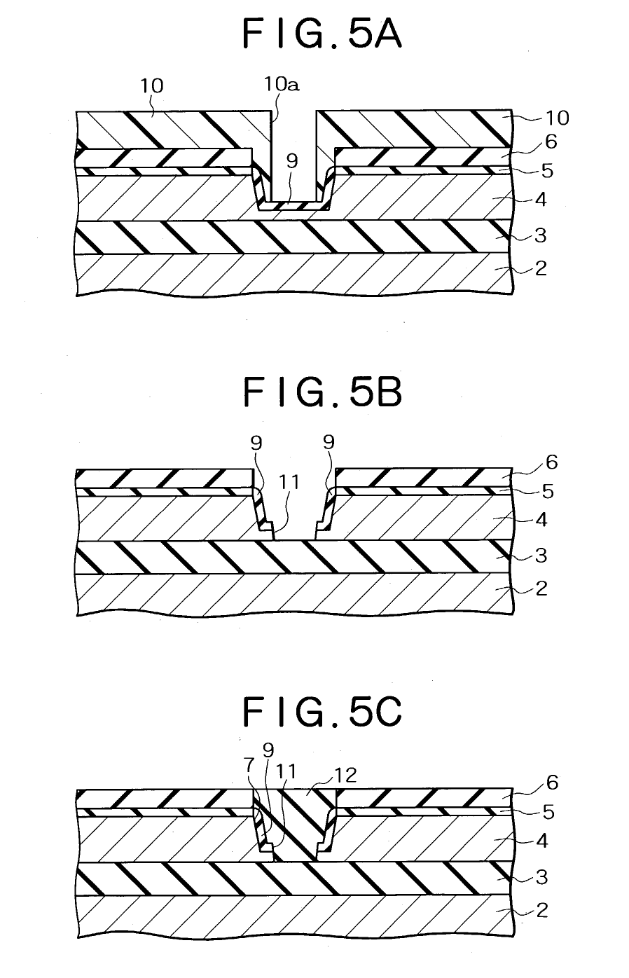

Preferred embodiments of the invention will be described below with reference to the accompanying drawings. To begin with, the first embodiment of the invention will be discussed. FIG. 5C is a cross-sectional view illustrating a semiconductor integrated circuit according to the embodiment. As shown in FIG. 5C, a BOX layer 3 is provided on a silicon substrate 2 and an SOI layer 4 is provided on the BOX layer 3. A silicon oxide film 5 and a silicon nitride film 6 are provided on the SOI layer 4. Trenches 7 which do not reach the BOX layer 3 are formed in the silicon nitride film 6, the silicon oxide film 5 and the SOI layer 4. An STI region 12 is buried in each trench 7 and a silicon oxide film 9 is formed on the sides of the trench 7. Further, a trench 11 which reaches the BOX layer 3 is formed in the bottom of the trench 7, and the STI region 12 is buried in the trench 11. The silicon oxide film 9 is not formed on the sides of the trench 11. A device (not shown), such as an MOSFET, is formed in a region in the SOI layer 4 which is defined by the STI region 12. The trench 7 and 11 are kinds of grooves.

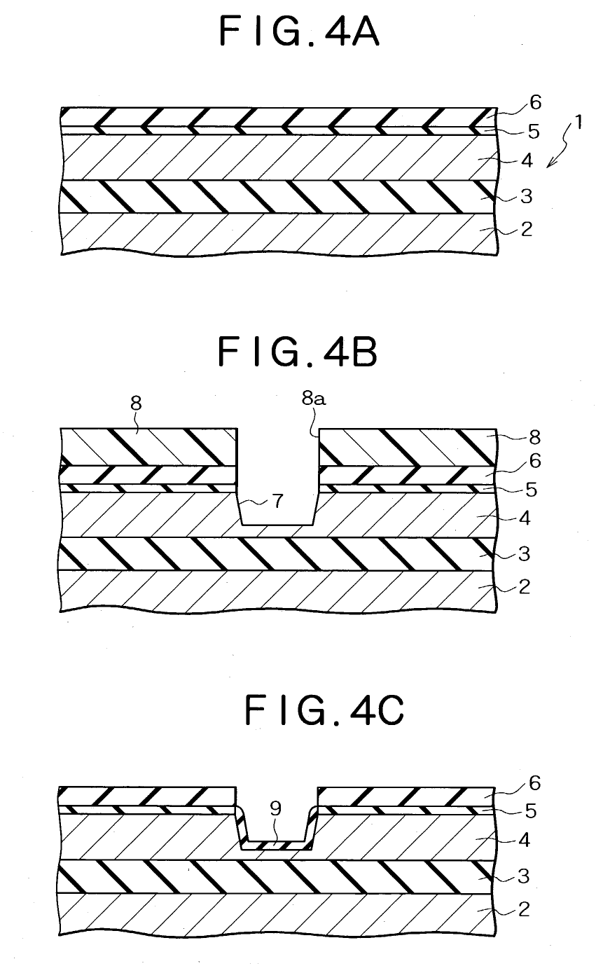

FIGS. 4A through 4C and FIGS. 5A through 5C are step-by-step cross-sectional views illustrating a method of forming the semiconductor integrated circuit according to the embodiment. First, as shown in FIG. 4A, a SOI wafer 1 which has the BOX layer 3 and the SOI layer 4 formed on the silicon substrate 2 is prepared. Then, the silicon oxide film (SiO₂ film) 5 is formed on the surface of the SOI layer 4 by thermal oxidation, and then the silicon nitride film (Si₃N₄ film) 6 is deposited by CVD. The thickness of the SOI layer 4 is, for example, 50 to 300 nm, the thickness of the silicon oxide film 5 is, for example, 3 to 20 nm, and the thickness of the silicon nitride film 6 is, for example, 50 to 200 nm.

Next, as shown in FIG. 4B, a photoresist 8 is formed on the silicon nitride film 6 by photolithography. Then, an opening 8a is formed in that region of this photoresist 8 which is reserved for the formation of an STI region in a later process. With the photoresist 8 as a mask, the silicon nitride film 6, the silicon oxide film 5 and the SOI layer 4 are selectively etched out by dry etching, thereby forming the trenches 7. At this time, CF₄, for example, is used as an etching gas under a gas pressure of, for example, 0.7 to 6.7 Pa in dry-etching the silicon nitride film 6 and the silicon oxide film 5, and a mixed gas of Cl₂ and O₂, for example, is used as an etching gas under a gas pressure of, for example, 1 to 10 Pa in dry-etching the SOI layer 4. The dry-etching is stopped in a middle of the SOI layer 4 so that the trenches 7 do not reach the BOX layer 3. At this time, the thickness of the SOI layer 4 on the bottoms of the trenches 7 is, for example, 30 to 250 nm. Then, the photoresist 8 is removed.

Next, round oxidation is executed by performing thermal oxidation on the SOI wafer 1. The thermal oxidation is carried out by placing the SOI wafer 1 in the atmosphere where, for example, the gas composition is H₂—O₂, the pressure is normal and the temperature is in a range of 800 to 1100° C., for 5 to 30 minutes. This oxidizes that region of the SOI layer 4 which corresponds to the bottom and sides of each trench 7 to thereby form the silicon oxide film 9 in that region. The thickness of the silicon oxide film 9 is, for example, to 5 to 30 nm in both the sides and bottom of the trench 7.

Next, as shown in FIG. 5A, a photoresist 10 is formed on the silicon nitride film 6. Then, an opening 10a is formed in that region of the photoresist 10 which corresponds to the bottom of at least one trench 7 by photolithography.. That is, the opening 10a is formed in such a way as to be positioned inside the trench 7 as seen from a direction perpendicular to the surface of the BOX layer 3.

Next, as shown in FIG. 5B, with the photoresist 10 (see FIG. 5A) as a mask, the SOI layer 4 which is positioned on the bottom of the trench 7 is selectively etched out, thereby forming the trench 11 that reaches the BOX layer 3. In this dry etching, for example, HBrO₂ is used as an etching gas and the gas pressure is, for example, 0.5 to 30 Pa. Thereafter, the photoresist 10 is removed.

Next, as shown in FIG. 5C, a silicon oxide film (not shown) is deposited on the entire surface of-the SOI wafer 1 by plasma CVD. At this time, the silicon oxide film is also buried inside the trenches 7 and 11. Then, the silicon oxide film that is formed in other regions than inside the trenches 7 and 11 is removed by CMP, thereby forming the STI region 12, comprised of a silicon oxide film, inside the trenches 7 and 11. The bottom surface of the STI region 12 contacts the top surface of the BOX layer 3. A device, such as the MOSFET, is formed in that area of the SOI layer 4 which is defined by the STI region 12, thereby completing a semiconductor integrated circuit.

In the above-described process, after the trench 11 is formed by the second dry etching, round oxidation need not be performed but such may be carried out to form a silicon oxide film with a thickness of, for example, about 1 to 15 nm. Cleaning may be carried out by, for example, a cleaning device (ammoniated water) made by Branson after the trench 11 is formed.

While the opening 10a in the photoresist 10 may be formed in-the region which corresponds to the bottoms of all the trenches 7 in the process shown in FIG. 5A, the opening 10a may be formed only in the region which corresponds to the bottoms of some of the trenches 7. Accordingly, it is possible to form the trenches 11 only in the bottoms of those some trenches 7, not in the bottoms of the remaining trenches 7, in the process shown in FIG. 5B. As a result, the trenches that reach the BOX layer 3 and the trenches that do not reach the BOX-layer 3 can both be formed, so that the STI region that reaches the BOX layer 3 and the STI region that does not reach the BOX layer 3 can be formed separately in the same process.

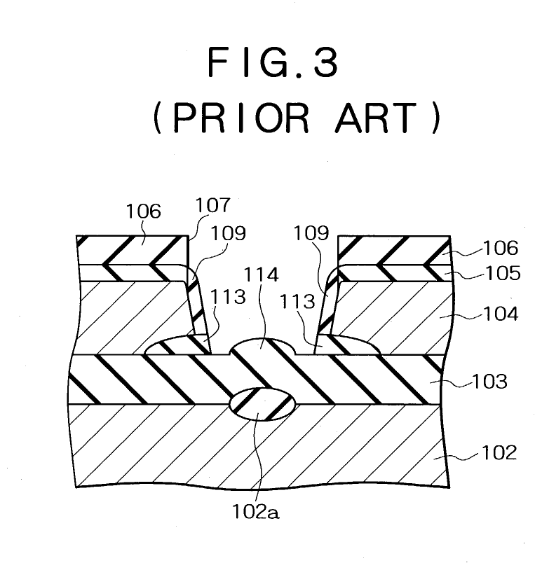

In the embodiment, the trenches 7 are formed in such a way as not to reach the BOX layer 3 in the process shown in FIG. 4B. Accordingly, oxygen does not go around and enter the interface between the BOX layer 3 and the SOI layer 4 at the time round oxidation is performed in the process shown in FIG. 4C. Therefore, the oxide 113 as shown in FIG. 3 is not produced. As the SOI layer 4 remains on the bottom of the trench 7 at the time of performing round oxidation, it is possible to restrain oxygen from penetrating the BOX layer 3 and reaching the silicon substrate 2. This makes it possible to suppress the production of the oxide film 102a as shown in FIG. 3, thereby suppressing the formation of the projections 114. It is therefore possible to prevent the SOI layer 4 from being bent by round oxidation and thus prevent the mobility of carriers in the transistor to be formed in the SOI layer 4 from dropping. As a result, the characteristics of the transistor can be prohibited from being degraded.

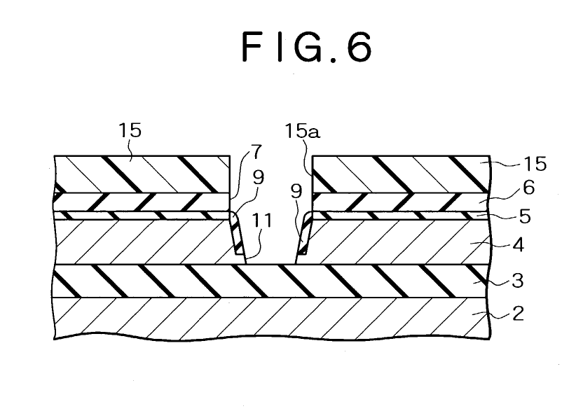

The second embodiment of the invention will now be discussed. FIG. 6 is a cross-sectional view illustrating a method of fabricating a semiconductor integrated circuit according to the embodiment. The structure of the semiconductor integrated circuit according to the second embodiment is similar to the structure of the semiconductor integrated circuit according to the first embodiment. First, a silicon oxide film 5 and a silicon nitride film 6 are formed on a SOI wafer 1, trenches 7 are formed with a photoresist 8 used as a mask, then round oxidation is performed to oxidize the inner surfaces of the trenches 7 to form a silicon oxide film 9 through the same processes as those in the first embodiment shown in FIGS. 4A to 4C.

Next, as shown in FIG. 6, a photoresist 15 which is patterned in the same pattern as the photoresist 8 (see FIG. 4B) is formed on the silicon nitride film 6. That is, an opening 15a is formed in the photoresist 15 at the same position as the opening 8a (see FIG. 4B) formed in the photoresist 8. With the photoresist 15 as a mask, etching is performed. As a result, the silicon oxide film 9 and the SOI layer 4 which are positioned on the bottoms of the trenches 7 are selectively etched out, thereby forming trenches 11. At this time, CF₄, for example, is used as an etching gas under a gas pressure of, for example, 0.5 to 10 Pa in dry-etching the silicon oxide film 9, and a mixed gas of Cl₂ and O₂, for example, is used as an etching gas under a gas pressure of, for example, 1 to 10 Pa in dry-etching the SOI layer 4. In this etching, that portion which is formed on the bottom of the trench 7 is selectively etched, so that those portions which are formed on the sides of the trench 7 are not completely removed by this etching. Thereafter, the photoresist 15 is removed.

Next, as shown in FIG. 5C, an STI region 12 is formed by the same scheme as used in the first embodiment. Then, a device, such as an MOSFET, is formed in that area of the SOI layer 4 which is defined by the STI region 12, thereby completing a semiconductor integrated circuit.

In addition to the advantages of the first embodiment, the second embodiment has an advantage such that the photoresist 15 which is used in the second etching can be formed with the same mask as used for the photoresist 8 which is used in the first etching. This advantage can allow the STI region 12 to be formed with a single mask and can thus contribute to lowering the fabrication cost for the semiconductor integrated circuit.

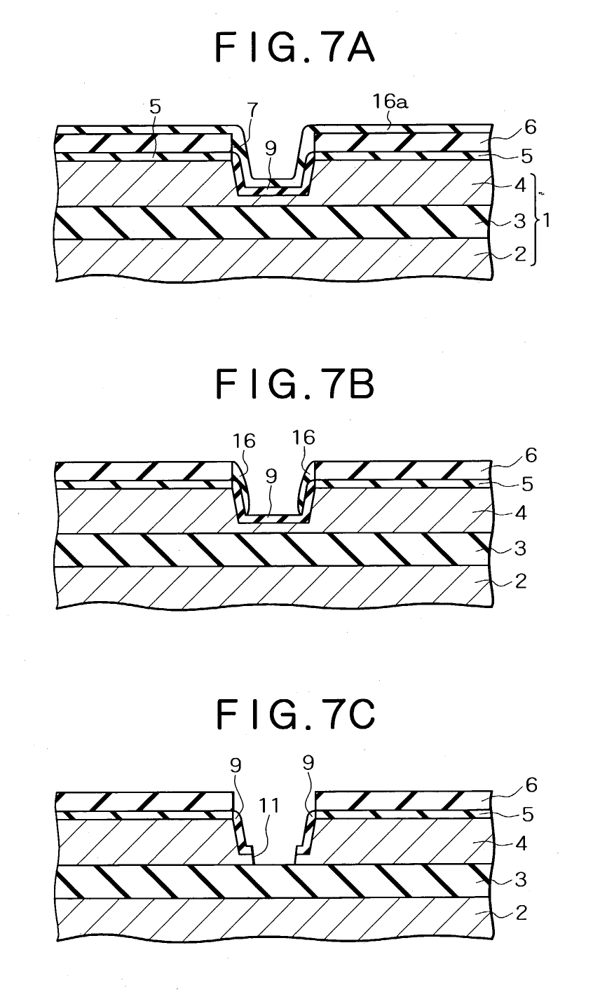

The third embodiment of the invention will now be discussed. FIGS. 7A to 7C are step-by-step cross-sectional views illustrating a method of fabricating a semiconductor integrated circuit according to the third embodiment. The structure of the semiconductor integrated circuit according to this embodiment is similar to the structure of the semiconductor integrated circuit according to the first embodiment. First, a silicon oxide film 5 and a silicon nitride film 6 are formed on a SOI wafer 1, trenches 7 are formed with a photoresist 8 used as a mask, then round oxidation is performed to oxidize the inner surfaces of the trenches 7 to form a silicon oxide film 9 through the same processes as those in the first embodiment shown in FIGS. 4A to 4C.

Next, as shown in FIG. 7A, a silicon nitride film (SiN film) 16a is deposited on the entire surface of the resultant structure by CVD. At this time, the deposition conditions for the silicon nitride film 16a are, for example, the temperature of 650 to 750° C., a source gas of NH₃—SiH₂Cl₂, the pressure of 10 to 140 Pa and the film thickness of about 10 to 100 nm.

Next, as shown in FIG. 7B, etch-back is carried out under the conditions that the etching gas is, for example, CF₄ and the pressure is, for example, 0.5 to 10 Pa to remove those portions of the silicon nitride film 16a which are formed on other regions than the sides of the trenches 7 and leave the portions formed on the sides of the trenches 7. Accordingly, side walls 16 of SiN are formed on the sides of each trench 7. At this time, the thickness of the side walls 16 is, for example, 10 to 50 nm.

Next, as shown in FIG. 7C, with the silicon nitride film 6 and the side walls 16 (see FIG. 7B) as masks, etching is performed under the conditions such that HBrO₂, for example, is used as the etching gas and the pressure is, for example, 0.5 to 30 Pa. This etching selectively removes the silicon oxide film 9 and the SOI layer 4 which are positioned on the bottoms of the trenches 7 to thereby form trenches 11 which reach the BOX layer 3. Next, the side walls 16 are removed by wet etching. At this time, phosphoric acid is used as an etchant. The process of removing the side walls 16 may be omitted.

Next, as shown in FIG. 5C, an STI region 12 is formed in the same scheme as used in the first embodiment. Then, a device, such as an MOSFET, is formed in that area of the SOI layer 4 which is defined by the STI region 12, thereby completing a semiconductor integrated circuit.

In the process shown in FIG. 7C, the photoresist (not shown) may be formed and patterned to expose some of the trenches 7 and cover the remaining trenches 7 before etching to form the trenches 11 is performed. This can allow the trenches 11 to be formed only in the bottoms of some exposed trenches 7 and prevent the trenches 11 from being formed in the bottoms of the remaining trenches 7. As a result, the trenches that reach the BOX layer 3 and the trenches that do not reach the BOX layer 3 can both be formed, so that the STI region that reaches the BOX layer 3 and the STI region that does not reach the BOX layer 3 can be formed separately in the same process.

In addition to the advantages of the first embodiment, the third embodiment has an advantage such that in the second etching, a new photoresist is not formed but the side walls 16 are used as a mask. At this time, as the side walls 16 are formed on the sides of the trenches 7, the second etching can be performed in a self-aligned manner with respect to the first etching. It is therefore possible to form a device isolation region small enough that a photoresist cannot be patterned and thus cope with the micro-fabrication of semiconductor integrated circuits.

What is claimed is:

1. A semiconductor integrated circuit comprising:
a semiconductor substrate;
an insulation film formed on said semiconductor substrate; and
a semiconductor layer formed on said insulation film and having first grooves in which an insulator is buried and on sides of which an oxide film of said semiconductor layer is formed in such a way as not to reach said insulation film, and a second groove in which an insulator is buried, which reaches said insulation film and which is formed in a bottom of at least one of said first grooves.

2. The semiconductor integrated circuit according to claim 1, wherein said second groove is formed only in bottoms of some of said first grooves and is not formed in bottoms of the remaining first grooves.

3. The semiconductor integrated circuit according to claim 1, wherein said semiconductor substrate is formed of silicon.

4. The semiconductor integrated circuit according to claim 1, wherein said semiconductor layer is formed of silicon.

5. The semiconductor integrated circuit according to claim 1, further comprising a transistor in a region defined by said first grooves in said semiconductor layer.

6. A method of fabricating a semiconductor integrated circuit, comprising the steps of:
forming an insulation film on a semiconductor substrate;
forming a semiconductor layer on said insulation film;
forming first grooves, which do not reach said insulation film, in a surface layer of said semiconductor layer;
oxidizing inner surfaces of said first grooves in said semiconductor layer;
forming a second groove, which reaches said insulation film, in a bottom of at least one of said first grooves; and
forming a device isolation region by burying an insulator in said first and second grooves.

7. The method according to claim 6, wherein said second groove is formed only in bottoms of some of said first grooves and is not formed in bottoms of the remaining first grooves.

8. The method according to claim 6, wherein said step of forming said second groove includes the step of:
forming a photoresist, having an opening at a region corresponding to said bottom of said at least one first groove, on said semiconductor layer; and
etching said semiconductor layer using said photoresist as a mask to thereby selectively remove said semiconductor layer located at said bottom of said at least one first groove.

9. The method according to claim 6, wherein said step of forming said first grooves includes the steps of:
forming a first photoresist on said semiconductor layer,
etching said semiconductor layer using said first photoresist as a mask to thereby selectively remove said semiconductor layer, and
removing said first photoresist; and
said step of forming said second-groove includes the steps of:
forming a second photoresist patterned in a same pattern as said first photoresist, and
etching said semiconductor layer using said second photoresist as a mask to thereby selectively remove said semiconductor layer located at said bottom of said at least one first groove.

10. The method according to claim 6, wherein said step of forming said second-groove includes the steps of:
forming side walls covering sides of said at least one first groove, and
etching said semiconductor layer using said side walls as a mask to thereby selectively remove said semiconductor layer located at said bottom of said at least one first groove.

11. The method according to claim 10, wherein said step of forming said side walls includes the steps of:
forming a nitride film on an entire surface of said semiconductor layer, and
performing etch-back of said nitride film to leave said nitride film formed on the sides of said at least one first groove and remove said nitride film formed on a region excluding said sides of said at least one first groove.

12. The method according to claim 6, wherein said semiconductor substrate is formed of silicon.

13. The method according to claim 6, wherein said semiconductor layer is formed of silicon.

14. The method according to claim 6, further comprising the step of forming an oxide film on said semiconductor layer and the step of forming a nitride film on said oxide film, between said step of forming said semiconductor layer and said step of forming said first grooves.

15. The method according to claim 6, wherein said step of oxidizing said inner surfaces of said first grooves is carried out by thermal oxidation.

16. The method according to claim 6, wherein said step of forming said device isolation region by burying an insulator in said first and second grooves includes the steps of:
forming a film of said insulator on an entire surface of said semiconductor layer, and
removing said film of the insulator which is formed in a region other than insides said first and second grooves.

17. The method according to claim 16, wherein said step of removing said film of the insulator is carried out by chemical mechanical polishing.

18. The method according to claim 6, further comprising the step of forming a transistor in a region defined by said device isolation region in said semiconductor layer.
